(19) United States
(12) Patent Application Publication
(10) Pub. No.: US 2024/0072512 A1
(43) Pub. Date: Feb. 29, 2024

(54) OPTICAL SEMICONDUCTOR DEVICE

(71) Applicant: Mitsubishi Electric Corporation, Tokyo (JP)

(72) Inventor: Masaki NASU, Tokyo (JP)

(73) Assignee: Mitsubishi Electric Corporation, Tokyo (JP)

(21) Appl. No.: 18/260,199

(22) PCT Filed: May 11, 2021
(86) PCT No.: PCT/JP2021/017919

§ 371 Date: Jun. 30, 2023

(51) Int. Cl. H01S 5/026; H01S 5/02212; H01S 5/02253; H01S 5/0231; H01S 5/02345; H01S 5/024; H01S 5/12

(52) U.S. Cl. CPC H01S 5/0265; H01S 5/02212; H01S 5/02253; H01S 5/0231; H01S 5/02345; H01S 5/02469; H01S 5/12; H01S 5/3434

(57) ABSTRACT

A first metal block (3) and a temperature control module (4) are mounted on the metal stem (1). A second metal block (5) is mounted on the temperature control module. First and second dielectric substrates (6,7) are mounted on side surfaces of the first and second metal blocks respectively. First and second signal lines (8,10) are provided on the first and second dielectric substrates respectively. A semiconductor optical modulation device (13) is mounted on the second dielectric substrate. A lens cap (19) is joined to the metal stem, is electrically connected to the metal stem, and airtightly seals the semiconductor optical modulation device and the like. A minimum distance between the first metal block and an inner wall of the lens cap is less than 0.37 mm. A minimum distance between the second metal block and the inner wall of the lens cap is less than 1.36 mm.

### FIELD

The present disclosure relates to an optical semiconductor device in which a semiconductor optical modulation device, etc. is airtightly sealed with a lens cap.

### BACKGROUND

In a mobile communication system and the like, a mobile communication terminal has become popular, and a data communication amount is drastically increased due to cloud migration of information. Along therewith, an optical communication system with a larger capacity is necessary, and an optical communication device that can transmit a signal of a large capacity at high speed is demanded. As a semiconductor optical integrated device that can perform high-speed communication, an EML (Electro-absorption Modulator integrated Laser) in which an electro-absorption modulator (EAM) and a distributed feedback laser diode (DFB-LD) are integrated is used.

An optical semiconductor device has been proposed in which a first metal block and a temperature control module are mounted on a metal stem, a second metal block is mounted on the temperature control module, first and second dielectric substrates are respectively mounted on side surfaces of the first and second metal blocks, and a semiconductor optical modulation device is mounted on the second dielectric substrate (for example, see PTL 1).

### CITATION LIST

### Patent Literature

[PTL 1] JP 2011-197360 A

### SUMMARY

### Technical Problem

In a case where a lens cap is mounted on the device disclosed in PTL 1, there is a problem that resonance occurs, a frequency band is limited, and an excellent optical waveform cannot be obtained. As a solution, an outer shape of the lens cap may be enlarged, and a resonance point may be shifted toward a high-frequency side. However, since a CAN package is required to be downsized, the outer shape of the lens cap cannot be enlarged.

The present disclosure has been made to solve the above-described problems, and an object of the present disclosure is to provide an optical semiconductor device that can obtain an excellent optical waveform without enlarging the outer shape of the lens cap.

### Solution to Problem

An optical semiconductor device according to the present disclosure includes: a metal stem; a lead pin penetrating through the metal stem; a first metal block mounted on an upper surface of the metal stem; a first dielectric substrate mounted on a side surface of the first metal block; a first signal line provided on the first dielectric substrate; a temperature control module mounted on the upper surface of the metal stem; a second metal block mounted on the temperature control module; a second dielectric substrate mounted on a side surface of the second metal block; a second signal line provided on the second dielectric substrate; a semiconductor optical modulation device mounted on the second dielectric substrate; a connection member connecting the lead pin and one end of the first signal line; a first bonding wire connecting the other end of the first signal line and one end of the second signal line; a second bonding wire connecting the other end of the second signal line and the semiconductor optical modulation device; and a lens cap joined to the upper surface of the metal stem, electrically connected to the metal stem, and airtightly sealing the first and second metal blocks, the first and second dielectric substrates, the temperature control module, the first and second signal lines, the semiconductor optical modulation device, the connection member, and the first and second bonding wires, wherein a minimum distance between the first metal block and an inner wall of the lens cap is less than 0.37 mm, and a minimum distance between the second metal block and the inner wall of the lens cap is less than 1.36 mm.

### Advantageous Effects of Invention

In the present disclosure, the minimum distance between the first metal block and the inner wall of the lens cap is made less than 0.37 mm, and the minimum distance between the second metal block and the inner wall of the lens cap is made less than 1.36 mm. As a result, the first and second metal blocks come close to the lens cap as the ground, and the ground is reinforced. Thus, the resonance points are reduced, the frequency response characteristics are improved, and broadband can be achieved. Accordingly, it is possible to obtain an excellent optical waveform without enlarging an outer shape of the lens cap.

### BRIEF DESCRIPTION OF THE DRAWINGS

FIG. 1 is a front-side perspective view illustrating an optical semiconductor device according to Embodiment 1.

FIG. 2 is a rear-side perspective view illustrating the optical semiconductor device according to Embodiment 1.

FIG. 3 is a top view illustrating inside of the optical semiconductor device according to Embodiment 1.

FIG. 4 is a front-side perspective view illustrating Modification 1 of the optical semiconductor device according to Embodiment 1.

FIG. 5 is a rear-side perspective view illustrating Modification 1 of the optical semiconductor device according to Embodiment 1.

FIG. 6 is a front-side perspective view illustrating Modification 2 of the optical semiconductor device according to Embodiment 1.

FIG. 7 is a rear-side perspective view illustrating Modification 2 of the optical semiconductor device according to Embodiment 1.

FIG. 8 is a diagram illustrating a simulation result of frequency response characteristics in a case where the minimum distance between the second metal block and the inner wall of the lens cap is varied.

FIG. 9 is a diagram illustrating a simulation result of frequency response characteristics in a case where the minimum distance between the first metal block and the inner wall of the lens cap is varied.

FIG. 10 is a diagram illustrating a three-dimensional electromagnetic field simulation result obtained by comparing the frequency response characteristics of the optical semiconductor device between a comparative example and Embodiment 1.

FIG. 11 is a front-side perspective view illustrating an optical semiconductor device according to Embodiment 2.

FIG. 12 is a rear-side perspective view illustrating the optical semiconductor device according to Embodiment 2.

FIG. 13 is a top view illustrating inside of the optical semiconductor device according to Embodiment 2.

FIG. 14 is a diagram illustrating a three-dimensional electromagnetic field simulation result obtained by comparing frequency response characteristics of the optical semiconductor device between the comparative example and Embodiment 2.

FIG. 15 is a front-side perspective view illustrating an optical semiconductor device according to Embodiment 3.

FIG. 16 is a rear-side perspective view illustrating the optical semiconductor device according to Embodiment 3.

FIG. 17 is a top view illustrating inside of the optical semiconductor device according to Embodiment 3.

FIG. 18 is a diagram illustrating a three-dimensional electromagnetic field simulation result obtained by comparing frequency response characteristics of the optical semiconductor device between the comparative example and Embodiment 3.

FIG. 19 is a cross-sectional view illustrating an optical semiconductor device according to Embodiment 4.

### DESCRIPTION OF EMBODIMENTS

An optical semiconductor device according to the embodiments of the present disclosure will be described with reference to the drawings. The same components will be denoted by the same symbols, and the repeated description thereof may be omitted.

### Embodiment 1

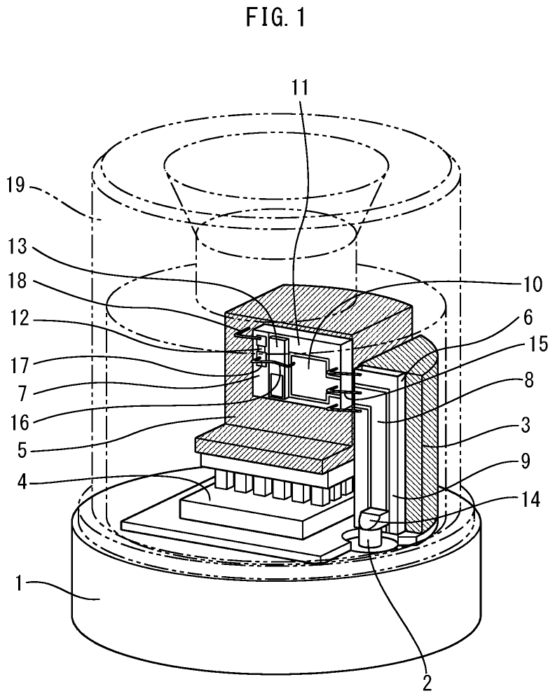

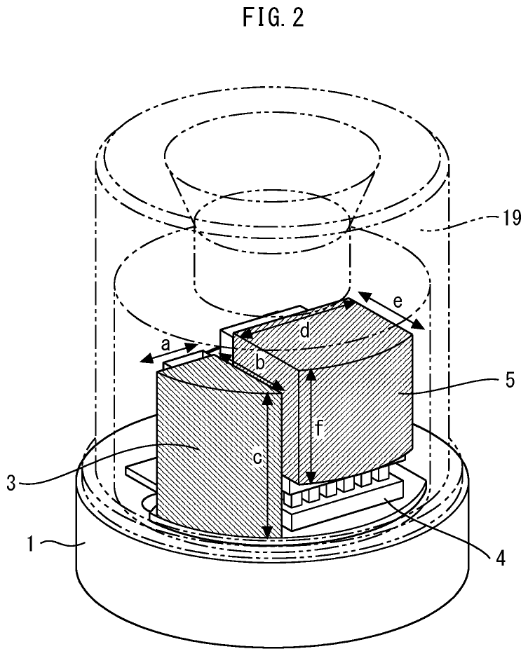

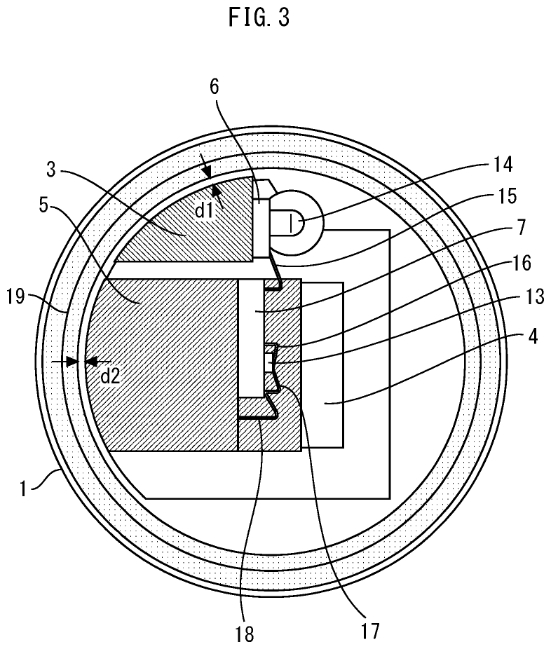

FIG. 1 is a front-side perspective view illustrating an optical semiconductor device according to Embodiment 1. FIG. 2 is a rear-side perspective view illustrating the optical semiconductor device according to Embodiment 1. FIG. 3 is a top view illustrating inside of the optical semiconductor device according to Embodiment 1.

A metal stem 1 has a circular plate shape. A lead pin 2 for a signal line penetrates through the metal stem 1, and is fixed to the metal stem 1 through a glass member. Each of the metal stem 1 and the lead pin 2 is made of a metal such as copper, iron, aluminum, and stainless, and a surface thereof may be subjected to gold plating, Nickel plating, or the like. Note that, in addition to the lead pin 2 for the signal line, a plurality of lead pins such as a lead pin for supplying power to a temperature control module, and a lead pin for supplying power to a laser diode unit when an EAM-LD is mounted, may be provided.

A first metal block 3 and a temperature control module 4 are mounted on an upper surface of the metal stem 1. The first metal block 3 is disposed near the lead pin 2. A second metal block 5 is mounted on the temperature control module 4. The first metal block 3 is made of a metal such as copper, iron, aluminum, and stainless. The first metal block 3 may has a structure in which an insulator made of ceramic, a resin, or the like is coated with a metal. The second metal block 5 is a block of a metal material in which a surface of a material having high heat conductivity, such as Cu is subjected to Au plating or the like. The temperature control module 4 includes a Peltier device sandwiched between a heat radiation surface and a cooling surface. The heat radiation surface is joined to the metal stem 1, and the cooling surface is mounted with the second metal block 5. First and second dielectric substrates 6 and 7 are respectively mounted on side surfaces of the first and second metal blocks 3 and 5.

From a viewpoint of assembling performance, the metal block is separated into the first metal block 3 and the second metal block 5. Separating the metal block makes it possible to reduce a heat quantity flowing from outside into the second dielectric substrate 7 and the second metal block 5 through the metal stem 1. Accordingly, it is possible to reduce power consumption of the temperature control module 4.

A first signal line 8 and a ground conductor 9 are provided on the first dielectric substrate 6. The first signal line 8 and the ground conductor 9 are disposed at a fixed interval to form a coplanar line. The ground conductor 9 is connected to the first metal block 3 through a via (not illustrated) provided in the first dielectric substrate 6.

A second signal line 10, a ground conductor 11, and a matching resistor 12 are provided on the second dielectric substrate 7. The second signal line 10 and the ground conductor 11 are disposed at a fixed interval to form a coplanar line. The ground conductor 11 is also provided on a side surface of the second dielectric substrate 7.

A semiconductor optical modulation device 13 is mounted on the second dielectric substrate 7. The semiconductor optical modulation device 13 is, for example, a modulator integrated laser (EAM-LD) in which an electro-absorption modulator using an InGaAsP-based quantum well absorption layer and a distributed feedback laser diode are monolithically integrated, or a MZ (Mach-Zehnder) semiconductor optical modulator. Heat generated in the semiconductor optical modulation device 13 is diffused through the second metal block 5 and the metal stem 1.

A connection member 14 connects the lead pin 2 and one end of the first signal line 8. The connection member 14 is, for example, solder, or may be a bonding wire. A bonding wire 15 connects the other end of the first signal line 8 and one end of the second signal line 10. A bonding wire 16 connects the other end of the second signal line 10 and the semiconductor optical modulation device 13. A bonding wire 17 connects the semiconductor optical modulation device 13 and one end of the matching resistor 12. A bonding wire 18 connects the other end of the matching resistor 12 and the second metal block 5.

A lens cap 19 is joined to the upper surface of the metal stem 1, is electrically connected to the metal stem 1, and airtightly seals the first and second metal blocks 3 and 5, the first and second dielectric substrates 6 and 7, the temperature control module 4, the first and second signal lines 8 and 10, the semiconductor optical modulation device 13, the connection member 14, the bonding wires 15 to 18, and the like. The lens cap 19 is made of a metal such as copper, iron, aluminum, and stainless, and has a tapered shape or a straight shape. Alternatively, the lens cap 19 may has a structure in which an insulator made of ceramic, a resin, or the like is coated with a metal.

A lateral width of the first metal block 3 is denoted by a, a depth is denoted by b, and a height is denoted by c. A rear surface of the first metal block 3 has a curved surface shape along an inner wall of the lens cap 19 having a cylindrical shape. The lateral width a or the depth b of the first metal block 3 is made large as compared with an existing technique. Accordingly, the rear surface of the first metal block 3 and the inner wall of the lens cap 19 are close to each other. As a result, a minimum distance d1 between the first metal block 3 and the inner wall of the lens cap 19 is less than 0.37 mm, and is 0.10 mm in this example.

A lateral width of the second metal block 5 is denoted by d, a depth is denoted by e, and a height is denoted by f. A cross-sectional shape of the second metal block 5 has an L-shape, and a part of the side surface has a curved surface shape along the inner wall of the lens cap 19. The lateral width d or the depth e of the second metal block 5 is made large as compared with an existing technique. Accordingly, the side surface of the second metal block 5 and the inner wall of the lens cap 19 are close to each other. As a result, a minimum distance d2 between the second metal block 5 and the inner wall of the lens cap 19 is less than 1.36 mm, and is 0.10 mm in this example.

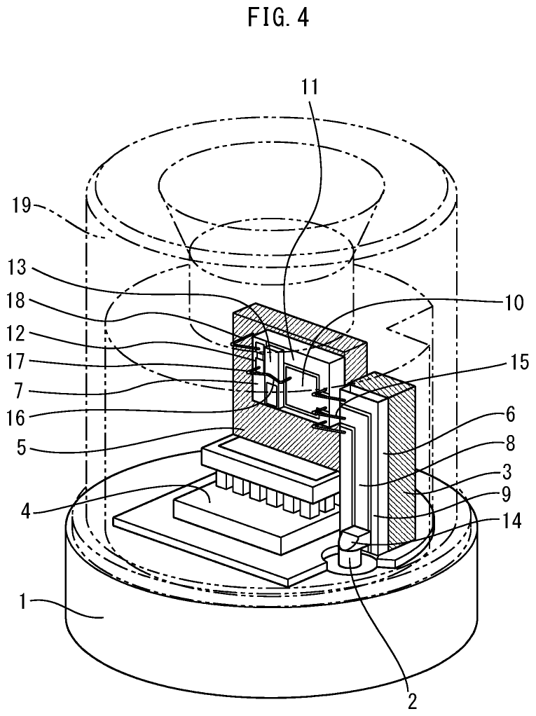

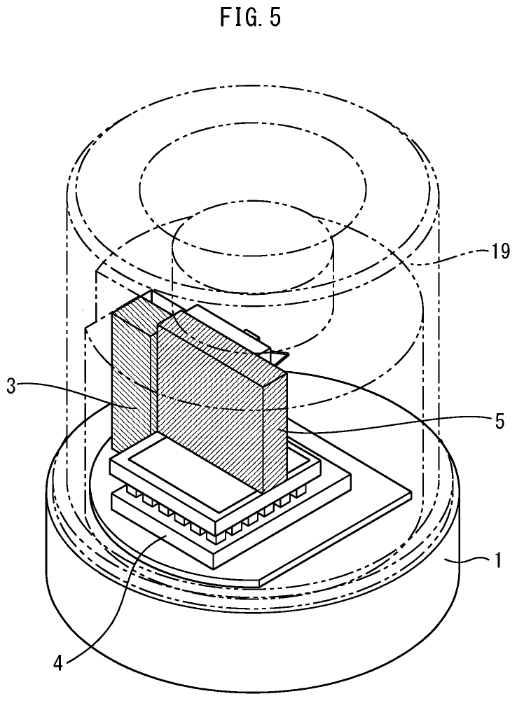

FIG. 4 is a front-side perspective view illustrating Modification 1 of the optical semiconductor device according to Embodiment 1. FIG. 5 is a rear-side perspective view illustrating Modification 1 of the optical semiconductor device according to Embodiment 1. The lens cap 19 has a cylindrical shape; however, a part of the inner wall of the lens cap 19 protrudes toward the first metal block 3. Accordingly, the inner wall of the lens cap 19 and the first metal block 3 are close to each other. The minimum distance d1 between the first metal block 3 and the inner wall of the lens cap 19 is less than 0.37 mm, and the minimum distance d2 between the second metal block 5 and the inner wall of the lens cap 19 is less than 1.36 mm.

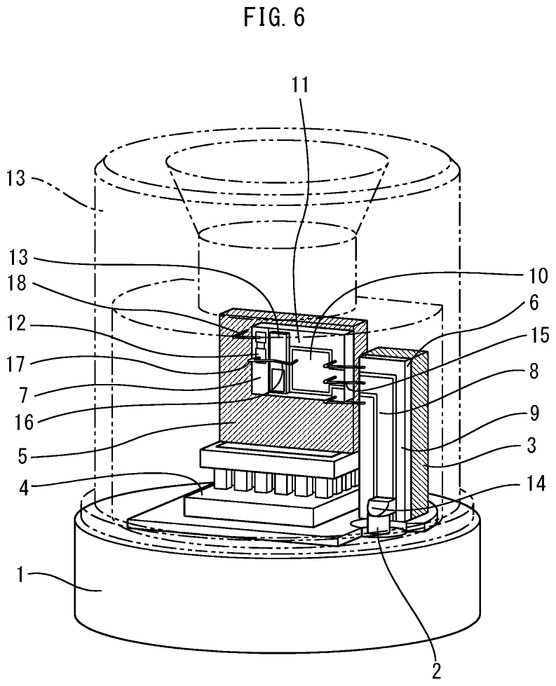

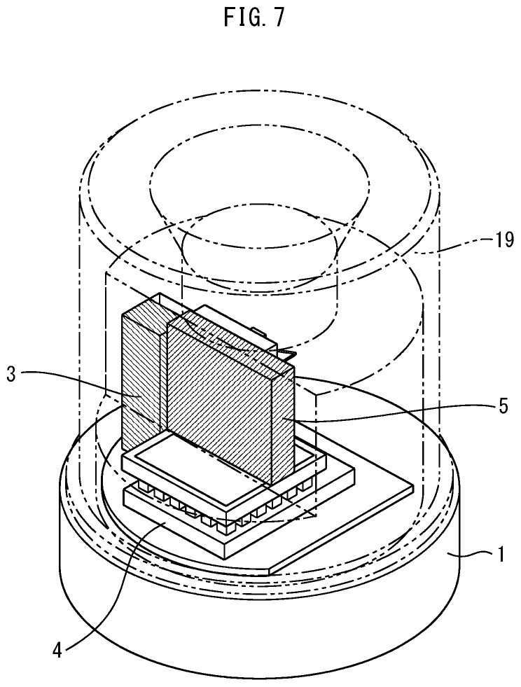

FIG. 6 is a front-side perspective view illustrating Modification 2 of the optical semiconductor device according to Embodiment 1. FIG. 7 is a rear-side perspective view illustrating Modification 2 of the optical semiconductor device according to Embodiment 1. A part of the internal wall of the lens cap 19 protrudes toward the first metal block 3 and the second metal block 5. Accordingly, the internal wall of the lens cap 19 and each of the first metal block 3 and the second metal block 5 are close to each other. The minimum distance d1 is less than 0.37 mm, and the minimum distance d2 is less than 1.36 mm.

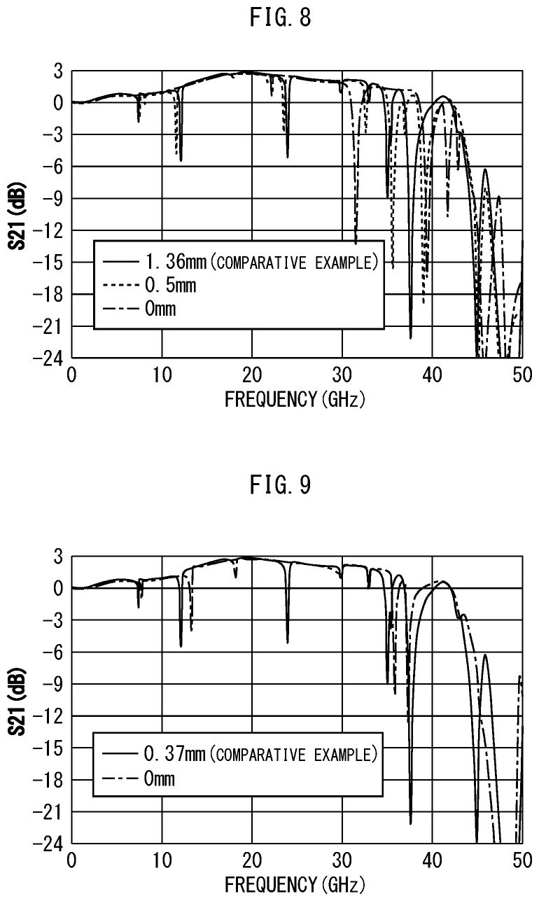

FIG. 8 is a diagram illustrating a simulation result of frequency response characteristics in a case where the minimum distance between the second metal block and the inner wall of the lens cap is varied. The frequency response characteristics are pass characteristics S21. The minimum distance d2 between the second metal block 5 and the inner wall of the lens cap 19 was set to 1.36 mm, 0.5 mm, and 0 mm. The distance between the first metal block 3 and the inner wall of the lens cap 19 was set to 0.37 mm in all cases. It is found that when the minimum distance d2 is less than 1.36 mm, drop caused by resonance is reduced in particular in a frequency domain up to 30 GHz, and the frequency response characteristics are improved.

FIG. 9 is a diagram illustrating a simulation result of frequency response characteristics in a case where the minimum distance between the first metal block and the inner wall of the lens cap is varied. The minimum distance d1 between the first metal block 3 and the inner wall of the lens cap 19 was set to 0.37 mm and 0 mm. The distance between the second metal block 5 and the inner wall of the lens cap 19 was set to 1.36 mm in all cases. It is found that when the minimum distance d1 is less than 0.37 mm, drop caused by resonance is reduced, and the frequency response characteristics are improved.

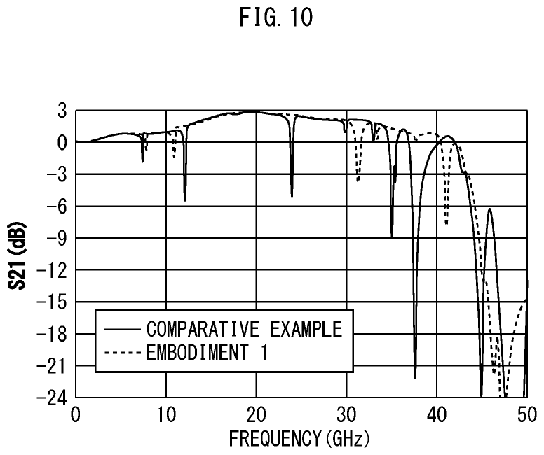

FIG. 10 is a diagram illustrating a three-dimensional electromagnetic field simulation result obtained by comparing the frequency response characteristics of the optical semiconductor device between a comparative example and Embodiment 1. In the comparative example, the minimum distance d2 is 1.36 mm, and the minimum distance d1 is 0.37 mm. It is found that, in Embodiment 1, resonance points are reduced, and drop of the frequency response characteristics is small, as compared with the comparative example.

As described above, in the present embodiment, the shapes of the first and second metal blocks 3 and 5 are changed from those in the comparative example, the minimum distance between the first metal block 3 and the inner wall of the lens cap 19 is made less than 0.37 mm, and the minimum distance between the second metal block 5 and the inner wall of the lens cap 19 is made less than 1.36 mm. As a result, the first and second metal blocks 3 and 5 come close to the lens cap 19 as the ground, and the ground is reinforced. Thus, the resonance points are reduced, the frequency response characteristics are improved, and broadband can be achieved. Accordingly, it is possible to obtain an excellent optical waveform without enlarging an outer shape of the lens cap 19.

### Embodiment 2

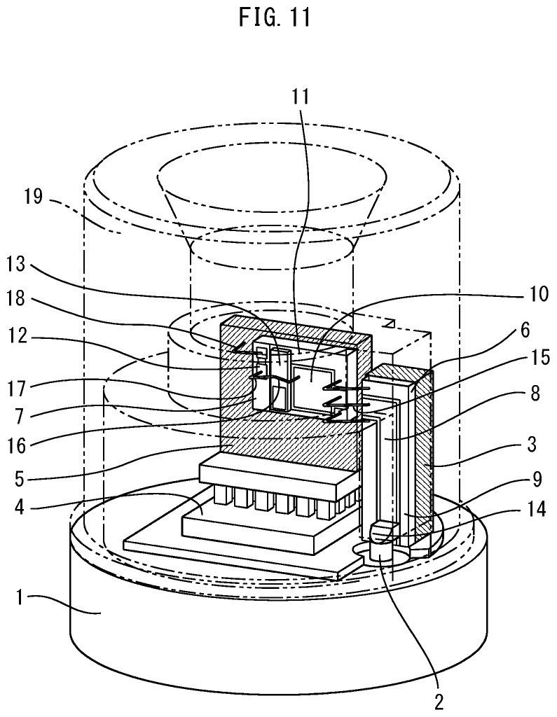

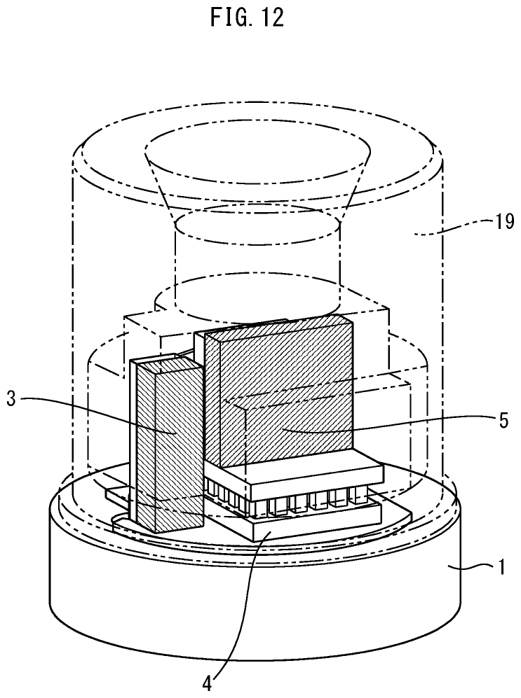

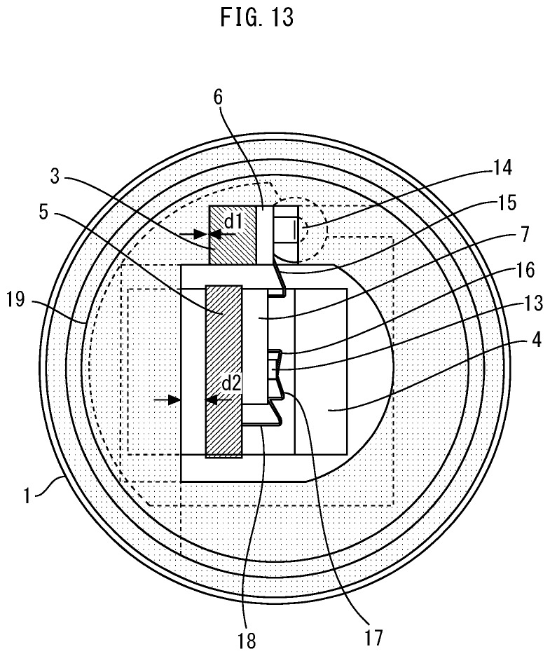

FIG. 11 is a front-side perspective view illustrating an optical semiconductor device according to Embodiment 2. FIG. 12 is a rear-side perspective view illustrating the optical semiconductor device according to Embodiment 2. FIG. 13 is a top view illustrating inside of the optical semiconductor device according to Embodiment 2.

In the present embodiment, the minimum distance d1 between the first metal block 3 and the inner wall of the lens cap 19 is 0 mm, and the minimum distance d2 between the second metal block 5 and the inner wall of the lens cap 19 is 0.30 mm. In other words, the first metal block 3 is in contact with the inner wall of the lens cap 19. A part of the inner wall of the lens cap 19 protrudes to come into contact with the rear surface of the first metal block 3. The structure is not limited thereto as long as the inner wall of the lens cap 19 comes into contact with one or a plurality of surfaces out of the side surface, the rear surface, and an upper surface of the first metal block 3.

Further, the first metal block 3 and the lens cap 19 may be electrically connected to each other by being bonded with solder, a conductive resin, or the like. For example, preliminary solder or a conductive resin is applied to the side surface or the rear surface of the first metal block 3, and heating is performed after the lens cap 19 is mounted, to bond the first metal block 3 and the lens cap 19.

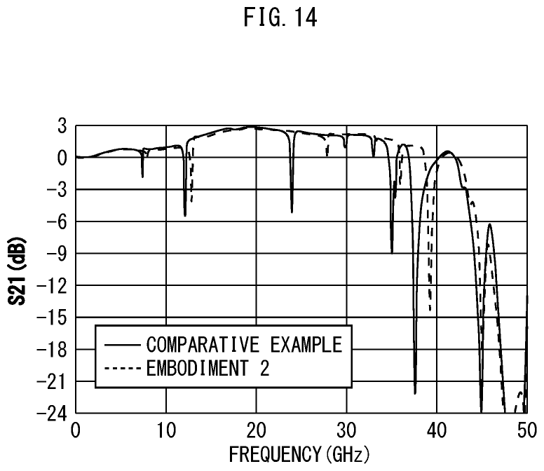

FIG. 14 is a diagram illustrating a three-dimensional electromagnetic field simulation result obtained by comparing frequency response characteristics of the optical semiconductor device between the comparative example and Embodiment 2. It is found that, in Embodiment 2, resonance points are reduced, and drop of the frequency response characteristics is small, as compared with the comparative example.

As described above, in the present embodiment, the lens cap 19 and the first metal block 3 are in contact with each other to reinforce the ground as compared with Embodiment 1. Thus, the resonance points are reduced, the frequency response characteristics are improved, and broadband can be achieved. Accordingly, it is possible to obtain an excellent optical waveform without enlarging the outer shape of the lens cap 19.

### Embodiment 3

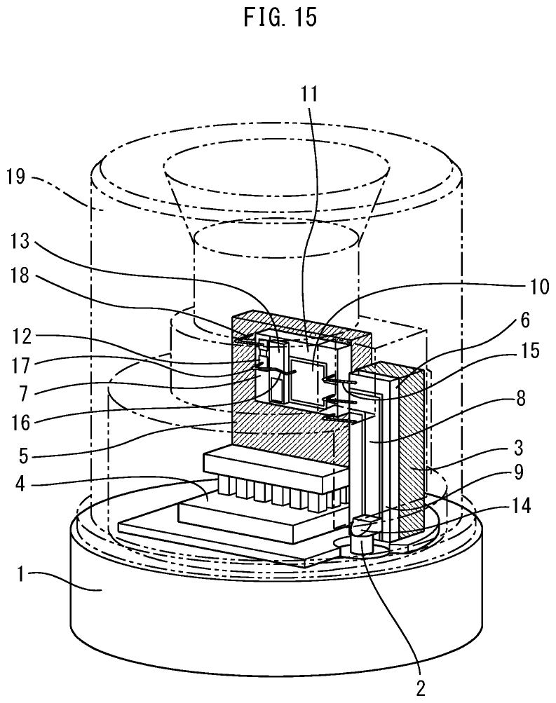

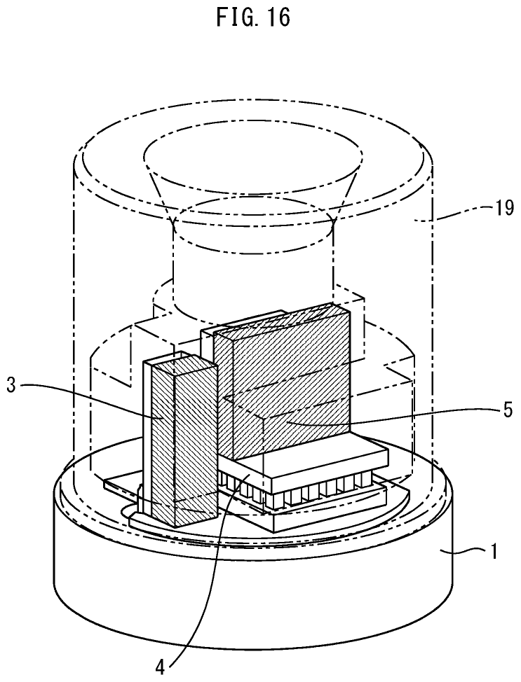

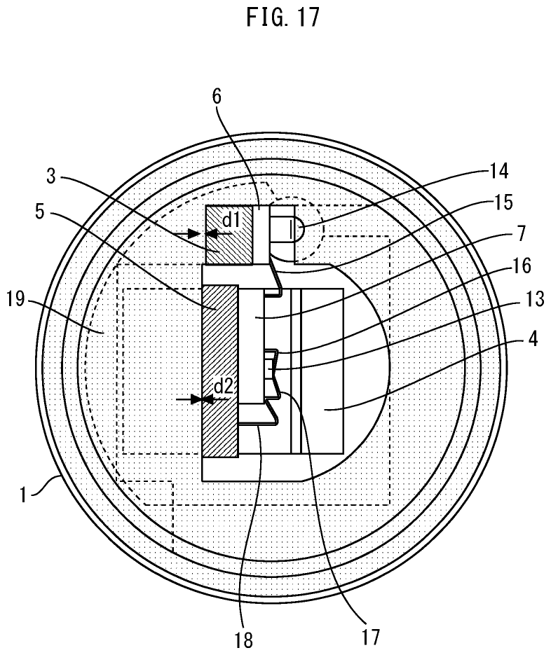

FIG. 15 is a front-side perspective view illustrating an optical semiconductor device according to Embodiment 3. FIG. 16 is a rear-side perspective view illustrating the optical semiconductor device according to Embodiment 3. FIG. 17 is a top view illustrating inside of the optical semiconductor device according to Embodiment 3.

In the present embodiment, the minimum distance d1 between the first metal block 3 and the inner wall of the lens cap 19 is 0 mm, and the minimum distance d2 between the second metal block 5 and the inner wall of the lens cap 19 is also 0 mm. In other words, not only the first metal block 3 but also the second metal block 5 are in contact with the inner wall of the lens cap 19.

A part of the inner wall of the lens cap 19 protrudes to come into contact with the side surface and the rear surface of the first metal block 3 and a rear surface of the second metal block 5. The structure is not limited thereto as long as the inner wall of the lens cap 19 comes into contact with one or a plurality of surfaces out of the side surface, the rear surface, and the upper surface of the first metal block 3, and one or a plurality of surfaces out of the rear surface and an upper surface of the second metal block 5.

Further, the first and second metal blocks 3 and 5 and the lens cap 19 may be electrically connected to each other by being bonded with solder, a conductive resin, or the like. For example, preliminary solder or a conductive resin is applied to the side surface or the rear surface of the first metal block 3 and the rear surface of the second metal block 5, and heating is performed after the lens cap 19 is mounted, to bond the first and second metal blocks 3 and 5 and the lens cap 19.

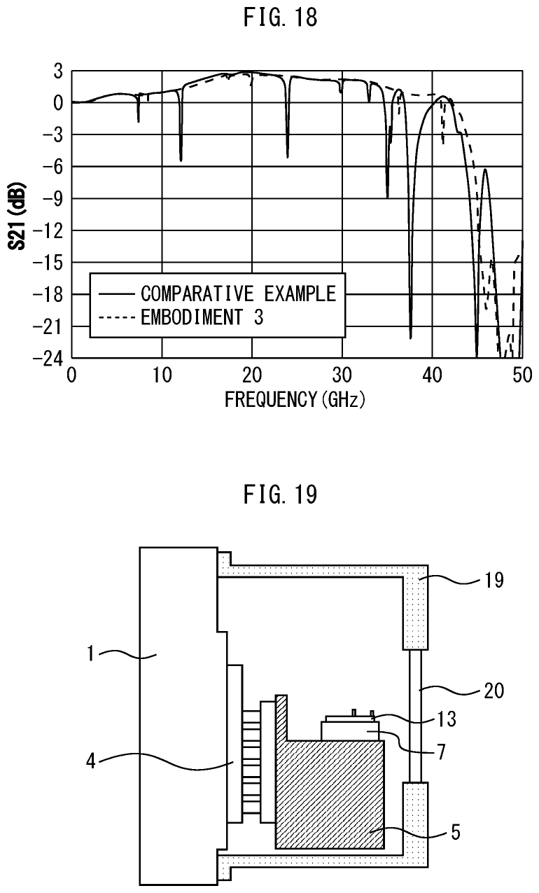

FIG. 18 is a diagram illustrating a three-dimensional electromagnetic field simulation result obtained by comparing frequency response characteristics of the optical semiconductor device between the comparative example and Embodiment 3. It is found that, in Embodiment 3, resonance points are reduced, and drop of the frequency response characteristics is small, as compared with the comparative example.

As described above, in the present embodiment, the lens cap 19 and the first and second metal blocks 3 and 5 are in contact with each other to reinforce the ground as compared with Embodiment 2. Thus, the resonance points are reduced, the frequency response characteristics are improved, and broadband can be achieved. Accordingly, it is possible to obtain an excellent optical waveform without enlarging the outer shape of the lens cap 19.

### Embodiment 4

FIG. 19 is a cross-sectional view illustrating an optical semiconductor device according to Embodiment 4. A lens of the lens cap 19 is a plate glass 20. Therefore, even if the positional relationship between the lens and the semiconductor optical modulation device 13 is deviated, optical characteristics such as a focal length and coupling efficiency are not influenced thereby. This makes it possible to mitigate structure variation and mounting accuracy of the lens cap 19. The other configurations and effects are similar to the configurations and effects according to Embodiment 1.

Further, the plate glass 20 can be applied to Embodiments 2 and 3. In this case, at least one of the first and second metal blocks 3 and 5 is in contact with the lens cap 19; however, influence of optical axis deviation can be ignored. Further, to prevent return light or etalon effect, the plate glass 20 may be joined to the lens cap 19 by tilting or imparting an angle to a thickness of the plate glass 20.

### REFERENCE SIGNS LIST

1 metal stem; 2 lead pin; 3 first metal block; 4 temperature control module; 5 second metal block; 6 first dielectric substrate; 7 second dielectric substrate; 8 first signal line; 10 second signal line; 13 semiconductor optical modulation device; 14 connection member; 15 bonding wire; 16 bonding wire; 19 lens cap; 20 plate glass

1. An optical semiconductor device comprising:
a metal stem;
a lead pin penetrating through the metal stem;
a first metal block mounted on an upper surface of the metal stem;
a first dielectric substrate mounted on a side surface of the first metal block;
a first signal line provided on the first dielectric substrate;
a temperature control module mounted on the upper surface of the metal stem;
a second metal block mounted on the temperature control module;
a second dielectric substrate mounted on a side surface of the second metal block;
a second signal line provided on the second dielectric substrate;
a semiconductor optical modulation device mounted on the second dielectric substrate;
a connection member connecting the lead pin and one end of the first signal line;
a first bonding wire connecting the other end of the first signal line and one end of the second signal line;
a second bonding wire connecting the other end of the second signal line and the semiconductor optical modulation device; and
a lens cap joined to the upper surface of the metal stem, electrically connected to the metal stem, and airtightly sealing the first and second metal blocks, the first and second dielectric substrates, the temperature control module, the first and second signal lines, the semiconductor optical modulation device, the connection member, and the first and second bonding wires,
wherein a minimum distance between the first metal block and an inner wall of the lens cap is less than 0.37 mm, and
a minimum distance between the second metal block and the inner wall of the lens cap is less than 1.36 mm.

2. The optical semiconductor device according to claim 1, wherein a part of the inner wall of the lens cap protrudes toward the first metal block.

3. The optical semiconductor device according to claim 1, wherein a part of the internal wall of the lens cap protrudes toward the first and the second metal blocks.

4. The optical semiconductor device according to claim 1, wherein the first metal block is in contact with the inner wall of the lens cap.

5. The optical semiconductor device according to claim 1, wherein the first and second metal blocks are in contact with the inner wall of the lens cap.

6. The optical semiconductor device according to claim 1, wherein a lens of the lens cap is a plate glass.
